(19) United States
(12) Patent Application Publication
(10) Pub. No.: US 2023/0323561 A1
(43) Pub. Date: Oct. 12, 2023

(54) METHOD OF GROWING A SINGLE-CRYSTAL SILICON

(71) Applicants: Zing Semiconductor Corporation, Shanghai (CN); Shanghai Institute of Microsystem and Information Technology, Chinese Academy of Sciences, Shanghai (CN)

(72) Inventors: Yinfeng LI, Shanghai (CN); Xing WEI, Shanghai (CN); Minghao LI, Shanghai (CN)

(73) Assignees: Zing Semiconductor Corporation, Shanghai (CN); Shanghai Institute of Microsystem and Information Technology, Chinese Academy of Sciences, Shanghai (CN)

(21) Appl. No.: 18/147,438

(22) Filed: Dec. 28, 2022

(30) Foreign Application Priority Data
Apr. 6, 2022 (CN) 202210359258.5

(51) Int. Cl. C30B 15/20; C30B 29/06; C30B 30/04

(52) U.S. Cl. CPC C30B 15/20; C30B 29/06; C30B 30/04

(57) ABSTRACT

The present invention provides a method of growing a single-crystal silicon, comprising: loading a batch of polysilicon material in a crucible of a furnace, heating the crucible to melt the polysilicon material into a mass of silicon melt, confirming a liquid surface of the mass of silicon melt, applying a superconducting magnetic field to the mass of silicon melt with a magnetic field generator and adjusting a position of the magnetic field generator to position a maximum point of the superconducting magnetic field within a predetermined range under the liquid surface, and dipping a seed crystal into the silicon melt, and pulling the seed crystal during rotation of the seed crystal to crystallize the single crystal under the seed crystal until forming an ingot of single-crystal silicon. Oxygen content in the ingot is controlled through positioning the maximum point of the superconducting magnetic field under the liquid surface. According to the present invention, it is needless to change heat field, cost is low and success rate to pull the single crystal is high.

### FIELD OF THE INVENTION

The present invention generally relates to a semiconductor technical field, and specifically, relates to a method of growing a single-crystal silicon.

### BACKGROUND OF THE INVENTION

Methods of growing a single crystal mainly comprise Czochralski (CZ) method, float zone (FZ) method and epitaxy method. The CZ method and FZ method are utilized for growing single-crystal silicon ingot, and the epitaxy method is utilized for growing single-crystal silicon film. The single crystal grown with the CZ method is mainly used for semiconductor integrated circuits, diodes, substrates with an Epi wafer, solar cells, etc., so that the CZ method is the most popular method growing the single crystal.

The CZ method makes a single crystal in a furnace with polycrystalline polysilicon material melt in a crucible. Then, a seed crystal is dipped into the melted silicon in the crucible, pulled during the rotation of the seed crystal and the crucible. A series of processes, such as neck, shoulder, crown, body, tail, cooling are undergone to obtain a single crystal ingot under the single crystal.

During the growth of the single crystal, silicon oxide in the crucible may become silicon and oxygen, either in movable atom form or in a loose bonding. When the quartz crucible is dissolved, oxygen may be transmitted to the silicon melt. Most oxygen moved to the silicon melt may vaporize from a free surface of the silicon melt, and the rest oxygen may segregate at a solid-liquid interface between the silicon melt and the grown single crystal and then enter the single crystal. Wafers made from the single crystal ingot with the CZ method are widely applied to the production of semiconductor electronic devices. However, oxygen, as the most impurity the action of which is the most complicate, has a great effect on the quality of the single crystal.

### SUMMARY OF THE INVENTION

Here, only simplified concepts are introduced, and details will be illustrated in the embodiments. It is to be understood that the description here is not meant as limitations of the invention, key feature, essential features or the scope of claims.

One aspect of the present invention is to provide a method of growing a single-crystal silicon, comprising steps of: loading a batch of polysilicon material in a crucible of a furnace, heating the crucible to melt the polysilicon material into a mass of silicon melt, confirming a liquid surface of the mass of silicon melt, applying a superconducting magnetic field to the mass of silicon melt with a magnetic field generator and adjusting a position of the magnetic field generator to position a maximum point of the superconducting magnetic field within a predetermined range under the liquid surface, and dipping a seed crystal into the silicon melt, and pulling the seed crystal during rotation of the seed crystal to crystallize the single crystal under the seed crystal until forming an ingot of single-crystal silicon.

Optionally, in an embodiment, the step of adjusting a position of the magnetic field generator may further comprise: confirming a target oxygen content of the single-crystal silicon, obtaining a pre-labeled target position for a maximum point of the superconducting magnetic field, corresponds to the target oxygen content, within the predetermined range under the liquid surface, and adjusting the position of the magnetic field generator to position the maximum point of the superconducting magnetic field at the pre-labeled target position.

Optionally, in an embodiment, the superconducting magnetic field may be a horizontal superconducting magnetic field.

Optionally, in an embodiment, the predetermined range may be 0-100 mm.

Optionally, in an embodiment, the method may further comprise: lifting the crucible during pulling the seed crystal to keep an absolute level of the liquid surface unchanged.

Optionally, in an embodiment, the step of adjusting a position of the magnetic field generator may further comprise: measuring the maximum point of the superconducting magnetic field, and adjusting the position of the magnetic field generator according to the measurement.

Optionally, in an embodiment, the step of adjusting a position of the magnetic field generator may further comprise: obtaining a relative position between the pre-labeled target position and the position of the magnetic field generator, and positioning the magnetic field generator according to the relative position to position the maximum point of the superconducting magnetic field within the predetermined range under the liquid surface.

According to a method of the growing a single-crystal silicon of the present invention, it is no need to change thermal field greatly to pull the single-crystal silicon successfully with a high success rate and low cost when applying the superconducting magnetic field to the silicon melt during crystallization and controlling the oxygen content in the ingot by positioning the maximum point of the superconducting magnetic field under the liquid surface of the silicon melt.

### BRIEF DESCRIPTION OF THE DRAWINGS

Various objects and advantages of the present invention will be more readily understood from the following detailed description when read in conjunction with the appended drawing, in which:

FIG. 1 shows a structural perspective view of a furnace according to an embodiment of the present invention;

FIG. 2 shows an exemplary flow chart of a method of growing a single-crystal silicon according to an embodiment of the present invention.

### DESCRIPTION OF EMBODIMENTS OF THE INVENTION

Great details are provided here so that this disclosure will be thorough, and will fully understand the present application to person skilled in the art. However, it will be apparent to the person skilled in the art that the present invention may be implemented without some of the specific detail(s). In some example embodiments, well-known features may not be described.

In addition to the detailed description, the present invention also may be implemented in other ways, but not meant to be limited by embodiments addressed here. On the contrary, the embodiments deliver a thorough understanding of the present invention, as well as claimed scope, to those skilled in the art. In the accompanying drawings, to express clearly, sizes and relative sizes of layers and areas may be exaggerated. The same labels are used for the same elements.

When an element or layer is described with terms of “above,” “adjacent to,” “connecting to” or “coupling to,” it is usually above, adjacent to, connecting to or coupling to other element directly or indirectly through any intervening element(s) or layer(s). On the contrary, when an element or layer is described with terms of “above . . . directly,” “adjacent to . . . directly,” “connecting to . . . directly” or “coupling to . . . directly,” it is clear that none of intervening element(s) or layer(s) exists. It is also to be understood that “first,” “second” and “third” are only exemplary for distinguishing elements, parts, areas, layers and/or portions, but not intended to imply relative importance or indicate actual quantity thereof. Therefore, the feature limited by “first,” “second” and “third” may be interchangeable.

Geometric terms of “below,” “under,” “underneath,” “above,” “on,” or “over,” etc. may be used to describe geometric relationship between an element or feature and one another. Axes system of the space shown in the drawings and environment when operating the device may be used. For example, when turning over a device in a drawing, elements or features described with “below,” “under,” “underneath,” originally may be changed to be above other element. As such, the term of “below” may be interpreted as comprising “below” and “above” for example. Other axes system, such as that with 90 degrees rotation, may be used for devices.

The terminology used here is for the purpose of describing particular embodiments only and is not intended to limit the present application. Singular forms of “a,” “an,” and “the” may be intended to include the plural forms as well, unless the context clearly indicates otherwise. The terms “or” usually comprise “and/or.” When one of these terms is used, existence of a feature, step, operation, element and/or part is ascertained without exclusion or addition of other feature, step, operation, element and/or part. The term of “and/or” comprise any combinations.

For a thorough understanding of the present invention, the details will be set forth in the following description in order to explain methods of growing a single-crystal silicon of the present invention. Preferred embodiments of the present invention are described in detail as follows, however, in addition to the detailed description, the present invention also may be implemented in other ways.

To solve the problem of unmanageable oxygen content in the single-crystal silicon ingot, circular oscillatory wave may be applied at a bottom of the crucible. The circular oscillatory wave may transport to the silicon melt, so as to speed up the movement of oxygen gas from a high content area to the free surface of the silicon melt, and eventually, the oxygen in the single-crystal silicon may be controlled. However, the circular oscillatory wave may affect stability of the melt and the quality of the crystal, and the circular oscillatory wave may need higher cost.

A superconducting magnetic field having a certain intensity may be applied during the crystallization to reduce the oxygen content in the pulled single-crystal silicon. Generally speaking, the higher the intensity the superconducting magnetic field has, the lower the oxygen content occurs. However, adjusting the intensity to control the oxygen content in the single-crystal silicon may affect stability of growth of the single-crystal silicon.

To solve aforesaid problems, according to a method of the growing a single-crystal silicon of the present embodiment, it is no need to change thermal field greatly to pull the single-crystal silicon successfully with a high success rate and low cost when applying the superconducting magnetic field to the silicon melt during crystallization and controlling the oxygen content in the ingot by positioning the maximum point of the superconducting magnetic field under the liquid surface of the silicon melt, so as to facilitate production of products with different oxygen contents with the same furnace.

To thoroughly understand the present invention, detailed structures and/or steps will be disclosed in the following paragraph to express the technical concept of the present invention. Preferred embodiments of the present invention will be illustrated; however, the present invention may be implemented in other applications.

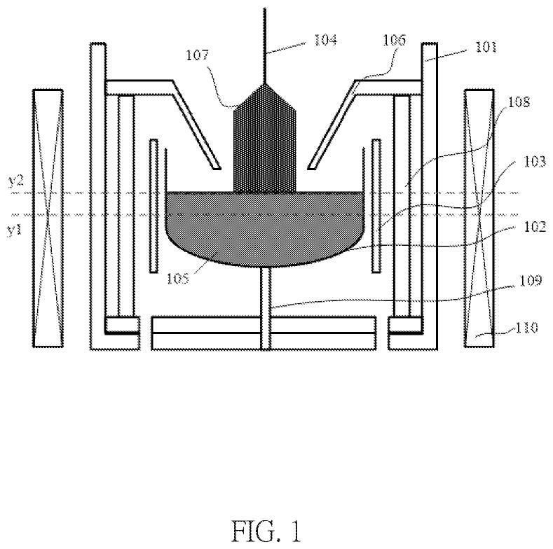

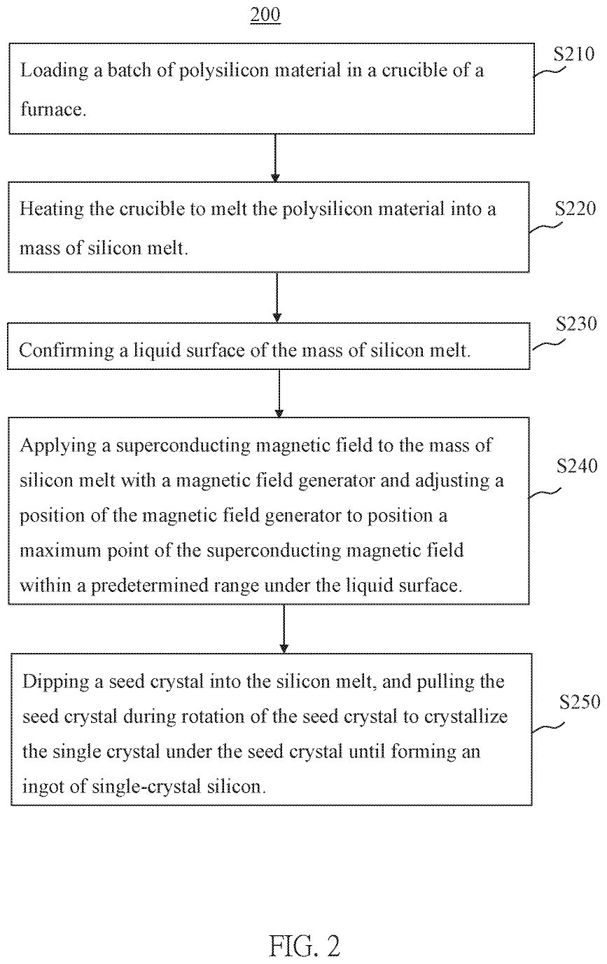

Referring to FIGS. 1 and 2 for details of a method of growing a single-crystal silicon of an embodiment according to the present invention.

Referring to FIG. 1, which shows a structural perspective view of a furnace according to an embodiment of the present invention, a furnace may be utilized for pulling a single-crystal silicon. The furnace at least comprises a body 101, a crucible 102, a heater 103, a cable 104 and a magnetic field generator 110.

Exemplarily, the crucible may comprise quartz crucible and graphite crucible. The quartz crucible may be utilized for receiving a batch of polysilicon material, such as polycrystalline silicon. The batch of polysilicon material may be heated to turn into a mass of silicon melt 105. The graphite crucible encloses the quartz crucible to support the quartz crucible during heating. The heater 103 is positioned outside of the graphite crucible to provide a heat source. A thermal insulation layer 108, such as a piece of carbon felt, is positioned at a sidewall of the body 101.

Above the crucible 102, a reflector 106 is positioned. The reflector 106 has a inverted tapered structure. The inverted tapered structure may be utilized for isolating the crucible 102 and protecting an ingot 107 from thermal radiation from the silicon melt 105 in the crucible 102, so as to speed up cooling of the ingot 107 and axial temperature gradient to speed up the growth of the ingot 107. Further, the inverted tapered structure may affect thermal field distribution of a surface of the silicon melt 105 to prevent from excessive difference of the axial temperature gradient at a center and rim of the ingot 107 to ensure stable growth between the ingot 107 and a liquid surface of the silicon melt 105. Meanwhile, the reflector 106 may be utilized for guiding inert gas introduced from a upper portion of the furnace to increase flow rate when passing through the surface of the silicon melt 105, so as to control the oxygen content and impurity content in the ingot 107.

The cable 104 is positioned above the crucible 102. A crystal is positioned at a bottom of the cable 104 through a clamp. A top of the cable 104 connects to a driver which drives the cable 104 to rotate and move upwards slowly at the same time. A crucible base 109 is positioned at the bottom of the crucible 102. A bottom of the crucible base 109 connects to a driver, so as to drive the crucible 102 to rotate. In the present embodiment, the crucible base 109 may lift the crucible 102 to keep the liquid surface of the silicon melt 105 in the crucible 102 unchanged, relative to the reflector 106 in height.

A magnetic field generator 110 is positioned outside the body 101 to apply a magnetic field to the silicon melt 105 which is served as an electric conductor. Then, the silicon melt may be affected by Lorentz force which is opposite to a direction of motion, so as to impede convection in the silicon melt 105 and increase viscosity of the silicon melt 105. As such, fewer impurities, such as oxygen, boron, aluminum, etc. from the crucible 102 enter the single-crystal silicon 107 through the silicon melt 105. A magnetic field created by the magnetic field generator 110 may be horizontal magnetic field, CUSP magnetic field or other magnetic field having other type of distribution form.

Referring to FIG. 2, a method of growing a single-crystal silicon may comprise steps of: step S210: loading a batch of polysilicon material in a crucible of a furnace; step S220: heating the crucible to melt the polysilicon material into a mass of silicon melt; step S230: confirming a liquid surface of the mass of silicon melt; step S240: applying a superconducting magnetic field to the mass of silicon melt with a magnetic field generator and adjusting a position of the magnetic field generator to position a maximum point of the superconducting magnetic field within a predetermined range under the liquid surface; and step S250: dipping a seed crystal into the silicon melt, and pulling the seed crystal during rotation of the seed crystal to crystallize the single crystal under the seed crystal until forming an ingot of single-crystal silicon.

Specifically, referring to FIG. 1, when growing the single-crystal silicon, at first, the batch of the polysilicon material, such as polycrystalline silicon, may be loaded into the crucible 102. Then, the furnace may be closed and vacuumed, and a protecting gas, such as argon gas, may be introduced into the furnace. Afterwards, the heater 103 is turned on to heat the polysilicon material to equal to or greater than a melting temperature at which the polysilicon material is melt into the silicon melt 105.

After the silicon melt 105 is formed, the liquid surface of the silicon melt 105 may be confirmed. Because the quantity of the batch of the polysilicon material may be different, the liquid surface may be different accordingly. To ensure a relative position between a maximum point of the applied superconducting magnetic field and the liquid surface, the liquid surface of the silicon melt 105 should be confirmed first. The liquid surface may be confirmed, but not limited to, with the quantity of the batch of the polysilicon material, crucible size, etc., observation of a user, or measurement of a sensor, etc.

After confirming the liquid surface, the magnetic field generator may be positioned accordingly to form the maximum point of the superconducting magnetic field in a predetermined range under the liquid surface, i.e. to ensure a height of the maximum point of the superconducting magnetic field is lower than a height of the liquid surface of the silicon melt and close to the liquid surface of the silicon melt, not the bottom of the crucible. Referring to FIG. 1, taking a horizontal magnetic field for example, magnetic lines of flux of the superconducting magnetic field, applied by the magnetic field generator, may horizontally pass through the silicon melt in the crucible. The liquid surface of the silicon melt 105 is indicated as y2, the maximum point of the superconducting magnetic field is indicated as y1, and the height of y1 is lower than that of y2.

Because liquid silicon melt is electrical conductor, when it is affected by the magnetic field, Lorentz force may be created in the silicon melt so as to inhibit natural convection of the silicon melt. When positioning the maximum point of the superconducting magnetic field within the predetermined range under the liquid surface of the silicon melt, greatest intensity of magnetic field may occur to impede convection of the silicon melt here greatly. Thus, fewer oxygen from the silicon melt may enter the ingot so as to reduce oxygen content in the ingot. As such, it is needless to intensively change thermal field of the furnace, with adjusting the position of the magnetic field alone, the oxygen content in the ingot may be controlled easily. Further, the cost is reduced.

Preferably, the predetermined range may be 0-100 mm, i.e. the maximum point of the superconducting magnetic field may be positioned within the range of 100 mm under the liquid surface of the silicon melt to present an ideal oxygen content.

Exemplarily, the magnetic field generator may be any form of magnetic field generator. For example, a superconducting coil having a pair or several pairs of superconducting magnets may be utilized to apply a horizontal magnetic field to the silicon melt in the crucible. The superconducting magnetic field may be CUSP magnetic field or other type of magnetic field having other distribution form the maximum point of which is below the liquid surface.

In the present embodiment, the maximum point of the superconducting magnetic field, not other physical position, may be taken as a reference point because the maximum point of the superconducting magnetic field has stronger correlation to the oxygen content of the single-crystal silicon.

In an example, the maximum point of the superconducting magnetic field may be a position exposing to a minimum oxygen content. Running some experiments in advance, the maximum point of the superconducting magnetic field which facilitates the minimum oxygen content in the single-crystal silicon may be found. During crystal growth, after confirming the liquid surface of the silicon melt, the maximum point of the superconducting magnetic field may be adjusted to the found position to increase the quality of the single-crystal silicon.

In another example, based on the correlation between the maximum point of the magnetic field of the oxygen content, relative position between the maximum point of the superconducting magnetic field and the liquid surface of the silicon melt may be adjusted through adjusting the position of the magnetic field generator so as to obtain a single-crystal silicon presenting the target oxygen content. As such, the same furnace may be used to obtain single-crystal silicon having different target oxygen contents. Specifically, the target oxygen content of the single-crystal silicon may be confirmed before crystal growth, a pre-labeled target position for a maximum point of the superconducting magnetic field may be obtained, corresponds to the target oxygen content, within the predetermined range under the liquid surface; and the position of the magnetic field generator may be adjusted to position the maximum point of the superconducting magnetic field at the pre-labeled target position. Running some experiments in advance, relation between the maximum point of the superconducting magnetic field and different oxygen contents in the single-crystal silicon may be found. Through adjusting the maximum point of the superconducting magnetic field to control the oxygen content of the single-crystal silicon, the oxygen content may be varied within 7 ppm-20 ppm.

When adjusting the position of the magnetic field generator, a relative position between the pre-labeled target position and the magnetic field generator may be obtained. Then, the magnetic field generator may be positioned according to the relative position to form the maximum point of the superconducting magnetic field within the predetermined range under the liquid surface or ensure the maximum point of the superconducting magnetic field at a target position in the predetermined range. For example, if the position A of the magnetic field generator corresponds to the maximum point of the superconducting magnetic field and the target position is 10 mm under the liquid surface of the silicon melt, the position A of the magnetic field generator may be positioned at 10 mm under the liquid surface.

Alternately, when adjusting the position of the magnetic field generator, the position of the maximum point of the superconducting magnetic field may be measured so as to adjust the position of the magnetic field generator according to the measurement to keep the maximum point of the superconducting magnetic field within the predetermined range under the liquid surface or further ensure the maximum point of the superconducting magnetic field at the target position in the predetermined range. For example, according to the measurement, if the maximum point of the superconducting magnetic field is in line with the liquid surface of the silicon melt and the target position is 10 mm under the liquid surface of the silicon melt, the magnetic field generator may be moved 10 mm downwardly.

After adjusting the position of the magnetic field, the seed crystal is dipped into the silicon melt. Through the driving of the seed cable, the seed crystal is rotated and gradually pulled to grow the single-crystal silicon following the seed crystal with the silicon atoms in the silicon melt. The seed crystal may be formed by cutting or drilling a single-crystal silicon having a certain lattice orientation, and usually in the shape of cylinder or cuboid. Through several stages of growth, such as neck, shoulder, crown, body, tail, and cooling, an ingot of the single-crystal silicon may be formed.

As mentioned above, the crucible base under the crucible may be provided. The crucible base may drive the crucible to rotation. As such, the silicon melt may be heated evenly to grow the ingot with an equal diameter. The crucible base of the present embodiment may be utilized to lift the crucible to keep the liquid surface at an unchanged absolute height, i.e. a distance between the liquid surface and the reflector is unchanged, during the growth of the ingot. With the premise that the maximum point of the superconducting magnetic field is fixed, the crucible base may ensure a distance between the maximum point of the superconducting magnetic field and the liquid surface of the silicon melt unchanged.

In some embodiments, after positioning the magnetic field generator before crystal growth, during the crystal growth, the position of the magnetic field generator may be unchanged so as to keep a stable oxygen content in the ingot. In some other embodiments, in different stages of crystal growth, the position of the magnetic field generator may be changed so as to change the position of the maximum point of the superconducting magnetic field in the predetermined range under the liquid surface of the silicon melt to obtain an ingot the oxygen content of which changes along with the changing of the stages of crystal growth.

To sum up, according to a method of the growing a single-crystal silicon of the present embodiment, it is no need to change thermal field greatly to pull the single-crystal silicon successfully with a high success rate and low cost when applying the superconducting magnetic field to the silicon melt during crystallization and controlling the oxygen content in the ingot by positioning the maximum point of the superconducting magnetic field under the liquid surface of the silicon melt, so as to facilitate production of products with different oxygen contents with the same furnace.

Although the exemplary embodiments are illustrated in conjunction with the appended drawing, it is to be understood that these embodiments are not meant as limitations of the invention but merely exemplary descriptions of the invention. Indeed, different adaptations may be apparent to those skilled in the art without departing from the scope of the annexed claims.

Similarly, to simplify and express the aspects of the present invention, each feature may be grouped into one embodiment, figure or its description. However, it is not intended to interpret the scope of the method of the present invention that more features are stated in the claimed scope than those actual stated in the claims. Specifically, as stated in the claims, the invention solves corresponding technical problem with features the number of which are less than a public solution. Therefore, each claim may be viewed as a single embodiment.

Those skilled in the art may understand how to create combinations with the features, steps or elements of the methods or apparatuses disclosed in the present application, including annexed claims, abstract and drawings. Unless explicit indication, each feature disclosed int the present application, including annexed claims, abstract and drawings, may be replaced by a replacement for a same, equal or similar object.

Further, those skilled in the art may understand that although some embodiment disclosed here may comprise some feature(s) in some other embodiment(s). The combination of different features implies that various embodiments may be provided within the claimed scope. For example, in the claims, any one embodiment to seek protection may be utilized in any combination.

Please note that aforesaid illustration is statement of the present invention, but not intended to limit the present invention. Those skilled in the art may design an alternate embodiment without departing from the scope of the annexed claims. In the claims, any punctuation marks between parentheses should not be used to limit the claimed scope. The present invention may be carried out with different hardware devices and proper programs. Some of the apparatus according to the present invention may be fulfilled with a claim claiming an apparatus. Terms of first, second and third do not denote an order, but a name.

While various embodiments in accordance with the disclosed principles been described above, it should be understood that they are presented by way of example only, and are not limiting. Thus, the breadth and scope of example embodiment(s) should not be limited by any of the above-described embodiments, but should be defined only in accordance with the claims and their equivalents issuing from this disclosure. In all instances, the scope of such claims shall be considered on their own merits in light of this disclosure, and such claims accordingly define the invention(s), and their equivalents or variations, that are protected thereby.

What is claimed is:

1. A method of growing a single-crystal silicon, comprising steps of:
loading a batch of polysilicon material in a crucible of a furnace;
heating the crucible to melt the polysilicon material into a mass of silicon melt;
confirming a liquid surface of the mass of silicon melt;
applying a superconducting magnetic field to the mass of silicon melt with a magnetic field generator and adjusting a position of the magnetic field generator to position a maximum point of the superconducting magnetic field within a predetermined range under the liquid surface; and
dipping a seed crystal into the silicon melt, and pulling the seed crystal during rotation of the seed crystal to crystallize the single crystal under the seed crystal until forming an ingot of single-crystal silicon.

2. The method of growing a single crystal according to claim 1, wherein the step of adjusting a position of the magnetic field generator further comprises:
confirming a target oxygen content of the single-crystal silicon;
obtaining a pre-labeled target position for a maximum point of the superconducting magnetic field, corresponds to the target oxygen content, within the predetermined range under the liquid surface; and
adjusting the position of the magnetic field generator to position the maximum point of the superconducting magnetic field at the pre-labeled target position.

3. The method of growing a single crystal according to claim 1, wherein the superconducting magnetic field is a horizontal superconducting magnetic field.

4. The method of growing a single crystal according to claim 1, wherein the predetermined range is 0-100 mm.

5. The method of growing a single crystal according to claim 1, further comprising:
lifting the crucible during pulling the seed crystal to keep an absolute level of the liquid surface unchanged.

6. The method of growing a single crystal according to claim 1, wherein the step of adjusting a position of the magnetic field generator further comprises:
measuring the maximum point of the superconducting magnetic field, and adjusting the position of the magnetic field generator according to the measurement.

7. The method of growing a single crystal according to claim 2, wherein the step of adjusting a position of the magnetic field generator further comprises:
obtaining a relative position between the pre-labeled target position and the position of the magnetic field generator; and
positioning the magnetic field generator according to the relative position to position the maximum point of the superconducting magnetic field within the predetermined range under the liquid surface.
